(19) United States
(12) Patent Application Publication
(10) Pub. No.: US 2022/0328708 A1
(43) Pub. Date: Oct. 13, 2022

(54) Solar Panel

(71) Applicant: Shri Dwarkeshji Bio Fuel LLC dba Green Elephant Log, Pueblo West, CO (US)

(72) Inventor: MUKUL B. PATEL, Pueblo, CO (US)

(21) Appl. No.: 17/657,886

(22) Filed: Apr. 4, 2022

Related U.S. Application Data
(60) Provisional application No. 63/201,032, filed on Apr. 9, 2021.

(51) Int. Cl. H01L 31/048; H02S 40/36

(52) U.S. Cl. CPC H01L 31/048; H02S 40/36

(57) ABSTRACT

A solar panel is disclosed as it may include a plurality of sequentially connected solar cells forming a panel structure. An example solar panel may include at least a first laminating sheet to laminate a first face of the panel structure and maintain the solar cells together as a part of the panel structure. A second laminating sheet may laminate a second face of the panel structure. The example solar panel may also include a first protective structure for a first face of the panel structure to provide structural support. A second protective structure may be provided for a second face of the panel structure. The laminated panel structure may be encapsulated by the first and second protective structures.

### PRIORITY CLAIM

This application claims the priority filing benefit of U.S. Provisional Patent Application No. 63/201,032 filed Apr. 9, 2021 for “Solar Panel” of Mukul B. Patel, hereby incorporated by reference in its entirety as though fully set forth herein.

### BACKGROUND

Solar panels are becoming more commonplace as a means for generating “clean” electricity via the sun. Consumers, however, are still reluctant to adopt solar panels for a number of reasons, such as but not limited to the delicate structure of a typical commercially viable solar panel. Solar panels are often somewhat delicate and susceptible to environmental conditions such as damaging wind, rain, and hail, and the debris that may be blown onto the solar panels during a storm. It is often not cost effective to make solar panels any more sturdy, and indeed, most mechanisms for enhancing solar panels, such as protective housings, may interfere with energy production.

### BRIEF DESCRIPTION OF THE DRAWINGS

FIG. 1 is a perspective view of example solar panels.

FIG. 2 is a high-level cross-sectional view of an example solar panel.

FIG. 3 is a close-up perspective view of an example protective structure for the solar panel.

FIG. 4 is a close-up perspective view of an interconnection device for connecting adjacent solar panels together.

### DETAILED DESCRIPTION

A solar panel is disclosed which can be assembled as relatively small, individual panes that are assembled together. In an example, the solar panel is lightweight and sturdy in structure, able to withstand many different environmental conditions.

An example solar panel includes a plurality of sequentially connected solar cells forming a panel structure. The example solar panel may also include a second laminating sheet to laminate a second face of the panel structure. The example solar panel may include at least a first laminating sheet to laminate a first face of the panel structure and maintain the solar cells together as a part of the panel structure. The example solar panel may include at least a first protective structure for a first face of the panel structure to provide structural support. The example solar panel may also include a second protective structure for a second face of the panel structure. In an example, the laminated panel structure is encapsulated by the protective structure(s). The protective structure(s) may be a multi-wall polycarbonate resin thermoplastic structure.

According to initial studies with a prototype solar panel devised according to the disclosure herein, the solar panel withstands simulated environmental impacts (e.g., water spray and hitting with snowballs) without degradation to the ability to produce reliable electricity.

In an example, the solar panel can be custom configured. As such, the solar panel may be installed at any suitable location, such as but not limited to, on garage doors (or implemented to replace some or all garage door panels). The solar panels can be made relatively small, and as such are readily installed in windows or on doors. In other examples, the solar panel can be installed inside the house by replacing vertical blinds in windows or clear glass doors. The solar panel can also be installed in more traditional locations, such as on the roof or ground.

Before continuing, it is noted that as used herein, the terms “includes” and “including” mean, but is not limited to, “includes” or “including” and “includes at least” or “including at least.” The term “based on” means “based on” and “based at least in part on.”

It is also noted that the examples described herein are provided for purposes of illustration, and are not intended to be limiting. Other devices and/or device configurations may be utilized to carry out the operations described herein.

The operations shown and described herein are provided to illustrate example implementations. It is noted that the operations are not limited to the ordering shown. Still other operations may also be implemented.

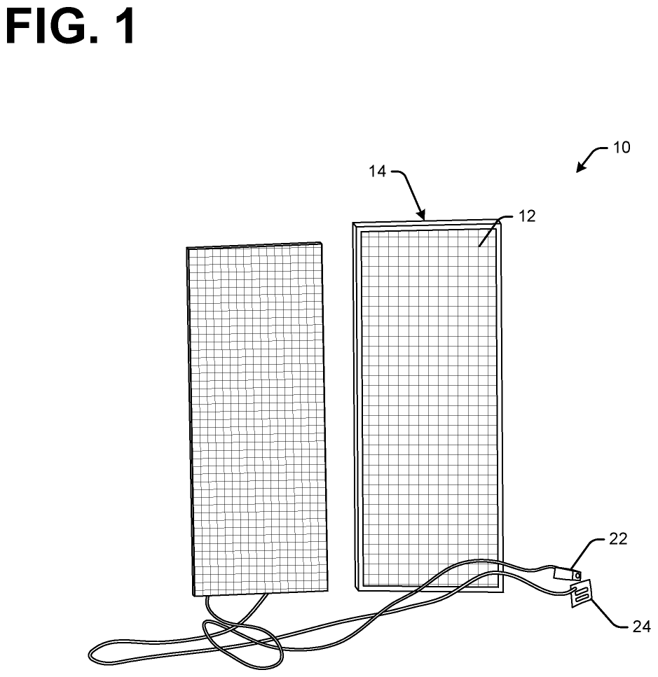

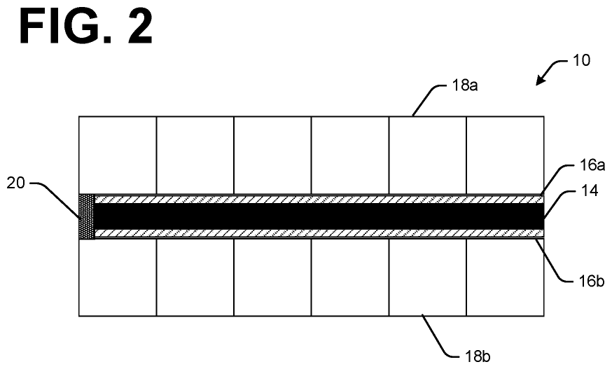

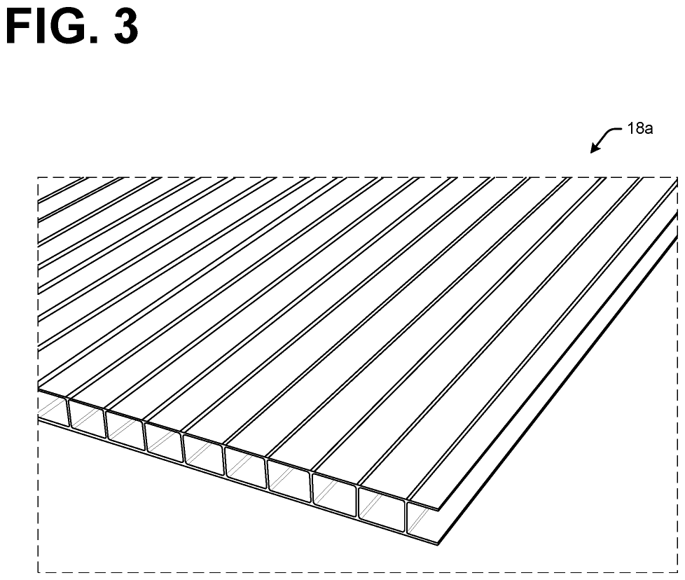

FIG. 1 is a perspective view of example solar panels 10. FIG. 2 is a high-level cross-sectional view of an example solar panel 10. FIG. 3 is a close-up perspective view of an example protective structure 12 for the solar panel 10 shown in FIG. 2.

An example solar panel 10 includes a plurality of sequentially connected solar cells 12 forming a panel structure 14. The example solar panel 10 may include at least a first laminating layer or “sheet” 16a to laminate a first face (e.g., sun facing side) of the panel structure 14. The laminating sheet 16a may maintain the solar cells together as a part of the panel structure 14. The example solar panel 10 may also include a second laminating layer or “sheet” 16b to laminate a second face (e.g., shadow side) of the panel structure 14.

The example solar panel 10 may include at least a first protective structure 18a for the first face of the panel structure 14 to provide structural support. The example solar panel 10 may also include a second protective structure 18b for a second face of the panel structure 12. In an example, the laminated panel structure is encapsulated by the protective structure(s). Although illustrated in FIG. 2 as separate structural elements, it is noted that the laminate layers 16a, 16b and the protective structure(s) 18a, 18b may be formed together as part of a single structural element that is provided over or encapsulating the panel structure 14.

An example solar panel 10 includes a plurality of solar cells 12 electrically connected (e.g., soldered sequentially) to increase the voltage level. For example, 40 laminated cells may provide up to about 20 volts/200 Watts of electricity.

During an example assembly operation, the individual solar cells 12 (or groups of cells) may be arranged in any desired configuration (e.g., size, shape, electrical output) to form the panel structure 14. For example, a lightweight adhesive tape may be provided to apply on the back face of the individual solar cells 12 (or groups of cells) to hold these together during assembly. The tape enables an individual user to electrically connect (e.g., to solder) the solar cells 12 (or groups of cells) and prepare the solar panel configuration from many smaller cells (or groups of solar cells) without the need for a large manufacturing facility. This may be particularly useful for individuals such as homeowners, so that a large quantity of solar cells 12 (or groups of cells) can be shipped to the end-user and then electrically connected together on site by the homeowner for custom configurations (e.g., a garage door installation).

During manufacture, the solar cells 12 (or groups of cells) or panel structure(s) 14 can be laminated (e.g., in a plastic laminate) to form laminate layers 16a, 16b. For example, laminating may be with plastic laminating sheets 16a, 16b using a laminator. The laminated structure (e.g., panel structure 14 and laminate layers 16a, 16b) is then provided with a protective structure(s) 18a, 18b. The protective structure(s) 18a, 18b may be bonded to or otherwise affixed to the laminated structure including panel structure 14 and laminate layer(s) 16a, 16b.

In an example, the protective structure (e.g., structure 18a) is provided on only one face of the laminated sheet 16a. For example, the protective structure 18 may be provided on the outward facing side of the solar cells 12 to protect the solar cells 12 from damage (e.g., people, the environment, sunlight, etc.).

In another example, the panel 14 including the solar cells 12 is protected on both the front and back faces by the protective structures (e.g., both structures 18a and 18b). For example, the panel 14 including the solar cells 12 may be encapsulated in the protective structure formed by structures 18a and 18b. The structures 18a and 18b may be hollow. For example, the structures 18a and 18b may be a corrugated structure.

In an example, the protective structure 18a, 18b is made at least in part of a polycarbonate resin thermoplastic sheet (e.g., LEXAN™). Polycarbonate resin thermoplastic sheets are sturdy in construction and stand up well to environmental impacts. The polycarbonate resin thermoplastic sheets tend to remain clear and stable without significant degradation over time. These sheets can sustain heavy rain, storm debris, wind, and snow, and still enable sufficient sunlight to pass to generate efficient solar electricity.

An example of a double-wall polycarbonate resin thermoplastic sheet that may be implemented as the protective structure 18a, 18b is shown in FIG. 3. One protective structure 18a may be provided for the front face of the solar panel 10 (e.g., sun facing). Another protective structure 18b may be provided on the back (shadow) face of the solar cells 12.

It is noted that although a generally hollow rectangular structure is illustrated in FIGS. 2 and 3, any suitable structure may be provided. In an example, a hollow structure provides strength and durability without adding weight. Examples of other structures may include but are not limited to a honeycomb. However, a lightweight solid protective structure may also be provided.

Encapsulation of the solar cells 12 according to the process described herein was shown with a prototype devised according to the disclosure herein, to double the wattage (e.g., up to about 400 Watts) available from the solar panels. This increase in efficiency may be due at least in part to protecting the solar cells 12 from the environment (e.g., humidity, rain) and degradation of the solar cells 12 (e.g., from UV radiation).

In an example, the solar cells 12 are insulated by at least the first protective structure. The solar cells may be sealed (e.g., by sealant 20 shown in the cross-sectional view in FIG. 2) from the external environment for moisture resistance at least in part by the first protective structure.

In an example, the solar panel 10 includes an external electrical connection to connect the solar cells 12 as an electrical power source. For example, the external electrical connection may be a screw termination leads 22 or a plug-in connector 24. The external electrical connection helps make hooking up (e.g., connecting appliances to the electricity generation of the solar cells) easy for the end-user. While some degree of installation knowledge may be required (e.g., provided with instructions), this may help to reduce and/or altogether eliminate the need for professional installation for many homeowners and other end-users.

In an example, the solar panel 10 is lightweight (e.g., individual panels may be about 5 pounds depending on size) due at least in part, to the hollow corrugated structure of the polycarbonate resin thermoplastic sheets (see, e.g., FIG. 3). In addition, the solar panel 10 may be insulated and sealed (e.g., on the sides and ends) for weather and moisture resistance.

In an example, the solar panel 10 can be installed on water (e.g., by floating) without the need for further structural support, as the support is provided by the protective structure 18a and/or 18b. Example installation on water includes, but is not limited to, ponds, rivers, lakes, or even swimming pools.

In an example, the durability and lightweight nature of the solar panel 10 makes it readily transported and moved from location to location. This makes the solar panel 10 accessible in off-grid or remote locations, and readily moved such as when a homeowner moves to a different home or a recreational vehicle (RV) owner moves sites.

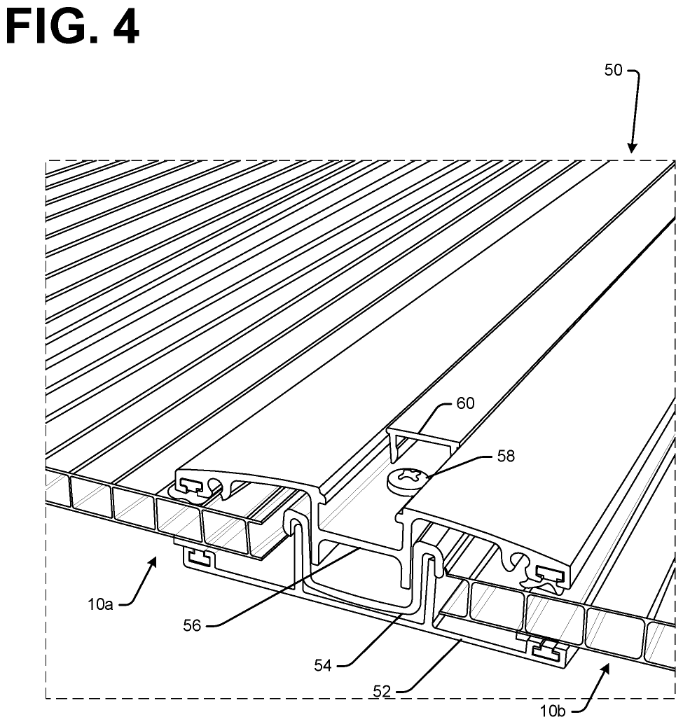

FIG. 4 is a close-up perspective view of an interconnection device 50 for connecting adjacent solar panels 10a, 10b together. Interconnection device 50 may be implemented to further configure the overall size, shape, and power generation of the solar panels 10. The interconnection device 50 includes a first connector 52, a channel structure 54, and a second connector 56. The edges of the adjacent solar panels 10a, 10b may be inserted into the interconnection device 50 between the first connector 52 and the second connector 56 and tighten together with fastener(s), e.g., screws 58. A protective and/or decorative cover 60 may be provided over the fasteners 58. The interconnection device 50 securely attaches the adjacent solar panels 10a, 10b to one another and can be implemented for any desired configuration.

As an example, a prototype of the solar panel 10 was constructed according to the disclosure herein. The prototype solar panel was about 2 feet by 5 feet and thin (e.g., about 3 MIL). The solar panel was then laminated and encapsulated in a commercial grade, clear, lightweight hollow LEXAN™ material.

The prototype solar panel was tested in a controlled environment, mounted in a house window facing inside and outside, and measured for electricity generation, efficiency, and performance. Later, this same prototype solar panel was placed in an open environment and exposed to wind, sunlight, rain, snow, and heat. Throughout the test, the prototype solar panel continued to generate electricity efficiently without measurable degradation in performance.

The prototype solar panel was tested in both controlled and typical outdoor environments. Throughout the test, the prototype solar panel continued to generate electricity efficiently without any noticeable degradation in performance.

It is noted that the examples shown and described are provided for purposes of illustration and are not intended to be limiting. Still other examples are also contemplated.

1. A solar panel, comprising:
a plurality of sequentially connected solar cells forming a panel structure;
at least a first laminating sheet to laminate a first face of the panel structure and maintain the solar cells together as a part of the panel structure; and
at least a first protective structure for a first face of the panel structure to provide structural support.

2. The solar panel of claim 1, further comprising a second laminating sheet to laminate a second face of the panel structure.

3. The solar panel of claim 1, wherein the laminated panel structure is encapsulated by at least the first protective structure.

4. The solar panel of claim 1, further comprising a second protective structure for a second face of the panel structure.

5. The solar panel of claim 4, wherein the laminated panel structure is encapsulated by the first and second protective structures.

6. The solar panel of claim 1, wherein the first protective structure is transparent.

7. The solar panel of claim 1, wherein the first protective structure is a multi-wall polycarbonate resin thermoplastic structure.

8. The solar panel of claim 1, wherein the first protective structure is a hollow structure.

9. The solar panel of claim 1, wherein the first protective structure is a corrugated structure.

10. The solar panel of claim 1, further comprising an external electrical connection to connect the solar cells as an electrical power source.

11. The solar panel of claim 10, wherein the external electrical connection is a screw termination.

12. The solar panel of claim 10, wherein the external electrical connection is a plug-in connector.

13. The solar panel of claim 1, further comprising a tape for the back of the solar cells to arrange and hold many small cells together for custom power output, shape, and size during manufacture.

14. The solar panel of claim 1, wherein the solar cells are insulated by at least the first protective structure.

15. The solar panel of claim 1, wherein the solar cells are sealed from the external environment for moisture resistance at least in part by the first protective structure.

16. A solar panel, comprising:
a plurality of sequentially connected solar cells forming a panel structure;
at least a first laminating sheet to laminate a first face of the panel structure and maintain the solar cells together as a part of the panel structure;
a first protective structure for a first face of the panel structure to provide structural support; and
a second protective structure for a second face of the panel structure;
wherein the laminated panel structure is encapsulated by the first and second protective structures.

17. The solar panel of claim 16, further comprising a second laminating sheet to laminate a second face of the panel structure;

18. The solar panel of claim 16, wherein the first and second protective structures form a transparent, corrugated, multi-wall polycarbonate resin thermoplastic outer structure.

19. A solar panel, comprising:
a plurality of sequentially connected solar cells forming a panel structure;
at least a first laminating sheet to laminate a first face of the panel structure and maintain the solar cells together as a part of the panel structure;
a second laminating sheet to laminate a second face of the panel structure;
a first protective structure for a first face of the panel structure to provide structural support; and
a second protective structure for a second face of the panel structure;
wherein the laminated panel structure is encapsulated by the first and second protective structures.

20. The solar panel of claim 19, wherein the first protective structure is a transparent, corrugated, multi-wall polycarbonate resin thermoplastic structure.
